(19) United States
(12) Patent Application Publication
(10) Pub. No.: US 2024/0047810 A1
(43) Pub. Date: Feb. 8, 2024

(54) SERIES FORMATION OF ELECTROCHEMICAL CELLS

(71) Applicant: 24M Technologies, Inc., Cambridge, MA (US)

(72) Inventors: Chad Alan HARTZOG, Columbus, IN (US); Junzheng CHEN, Concord, MA (US)

(21) Appl. No.: 18/228,923

(22) Filed: Aug. 1, 2023

Related U.S. Application Data
(60) Provisional application No. 63/394,341, filed on Aug. 2, 2022.

(51) Int. Cl. H01M 50/251; H01M 50/569; H02S 40/38; H02S 40/36; H01M 4/06

(52) U.S. Cl. CPC H01M 50/251; H01M 50/569; H02S 40/38; H02S 40/36; H01M 4/06; H01M 2220/10

(57) ABSTRACT

In some aspects a method of monitoring an electrochemical cell stack can include measuring an anode voltage difference between a first anode tab from a plurality of anode tabs and a second anode tab from the plurality of anode tabs, measuring a cathode voltage difference between a first cathode tab from a plurality of cathode tabs and a second cathode tab from the plurality of cathode tabs, and calculating a difference between the cathode voltage and the anode voltage. In some embodiments, the first cathode tab and the first anode tab can be located at a proximal end of the electrochemical cell. In some embodiments, a distance between the first anode tab and the second anode tab is within about 5% of the distance between the first cathode tab and the second cathode tab.

### CROSS-REFERENCE TO RELATED APPLICATIONS

This application claims priority to and the benefit of U.S. Provisional Patent Application No. 63/394,341 entitled, “Electrochemical Cells and Electrochemical Cell Stacks with Series Connections and Methods of Producing, Operating, and Monitoring the Same,” filed Aug. 2, 2022; the disclosure of which is incorporated herein by reference in its entirety.

### TECHNICAL FIELD

Embodiments described herein relate to methods of formation of electrochemical cells and electrochemical cell stacks.

### BACKGROUND

Existing lithium-ion manufacturing systems utilize individual cell formation systems where thousands or millions of cells are handled and processed via a formation process. Cells are then aged and degassed prior to installation. This processing is generally inefficient. Power systems for building electrochemical cells often operate at 0V-5V DC channels with very low power conversion efficiency. If the energy from discharge is not incorporated back into the grid, then 1 MWh of energy can be lost in the charging of each electrochemical cell. Additionally, conversion efficiency from a building grid to a production channel can be about 50-60%. Discharge system losses can also be about 5%. Conveyors and handling also add additional power load. Heating, ventilation, and air conditioning (HVAC) loading for removal of all the dissipated energy for discharge of the cells can add 1 MWh to the HVAC heat loading for the building, increasing tonnage for building systems. Total losses in a production system can be about 2.1 MWh for each 1 MWh produced, plus each additional 600 tons of refrigeration capacity may be necessary, assuming 1 MWh in Work in Progress (WIP). Capital cost is also a significant consideration. All of the equipment and machinery to move cells from one location to another during the formation process (e.g., conveyors, trays, baskets, fixtures, test channels, floorspace for formation aging and post-test) is an important aspect of the manufacture of each cell. Multiple locations and moves for each cell also increase the process complexity for the system and the cost of that system. The system size, complexity and cost are significant drivers for the inability to manufacture battery cells efficiently. Therefore, there is a need for more efficient systems and methods to store and transfer energy for manufacturing of electrochemical cells.

### SUMMARY

Embodiments described herein relate to systems and methods for forming electrochemical cells and electrochemical cell modules connected in series. In some aspects, a method of forming an electrochemical cell, the electrochemical cell including an anode material disposed on an anode current collector, a cathode material disposed on a cathode current collector, and a separator disposed between the anode material and the cathode material, includes transferring energy from an energy storage system to a battery formation system to charge the electrochemical cell, and transferring energy from the electrochemical cell to the energy storage system to prevent heat energy dissipation into the formation system, wherein the energy transferred is direct current (DC).

In some aspects, a system for forming an electrochemical cell module includes a first electrochemical cell module and a second electrochemical cell module connected in series, the first electrochemical cell module and the second electrochemical cell module configured to receive energy via an energy storage system; a first switch connected in series with the first electrochemical cell module and a second switch connected in parallel with the first electrochemical cell module. The first switch and the second switch have (1) a first configuration in which the first switch is closed and the second switch is open such that current moves through the first electrochemical cell module, and (2) a second configuration in which the first switch is open and the second switch is closed such that current moves directly to the second electrochemical cell module, bypassing the first electrochemical cell module. The system further includes a controller configured to transition the first switch and the second switch between the first configuration and the second configuration, thereby directing current flow to charge and discharge the first electrochemical cell module and second electrochemical cell module.

In some aspects, a system includes an energy storage system configured to receive energy from one or more power sources, and a formation system including a plurality of electrochemical cells connected in series and configured to control current flow through the plurality of electrochemical cells via a controller electrically coupled to a plurality of switches. The plurality of electrochemical cells connected to the energy storage system via a DC electrical connection such that energy is transferred between the plurality of electrochemical cells and the energy storage system without an AC transformer.

### BRIEF DESCRIPTION OF THE DRAWINGS

FIG. 1 shows a schematic block diagram of an electrochemical cell module, according to an embodiment.

FIG. 2 shows a schematic block diagram of energy transfer within a battery manufacturing campus, according to an embodiment.

FIG. 3 shows a schematic block diagram of energy transfer within a battery manufacturing campus, according to an embodiment.

FIG. 4 shows a diagram of an electrochemical cell stack formation system, according to an embodiment.

FIGS. 5A-5B show diagrams of a battery manufacturing campus including an energy storage system, according to an embodiment.

FIG. 6 shows a diagram of a station for traditional formation for an individual electrochemical cell.

FIG. 7 shows a diagram of a series formation of electrochemical cells with an energy storage system, according to an embodiment.

FIG. 8 shows the interaction between a solar array, an energy storage system, and a formation power system, according to an embodiment.

FIG. 9 is a flowchart of a method for forming an electrochemical cell module via an energy storage system, according to an embodiment.

FIG. 10 is a flowchart of a method for forming an electrochemical cell module via an energy storage system, according to an embodiment.

FIG. 11 is a flowchart of a method for providing backup power from an energy storage system, according to an embodiment.

FIG. 12 is a flowchart of a method for forming an electrochemical cell via an energy storage system, according to an embodiment.

### DETAILED DESCRIPTION

Embodiments described herein describe production of electrochemical cells as part of a module build. Module building can include a method of bypassing components of the battery formation system with current flow during formation of the electrochemical cell. High voltage cells, module and packs can be built and then the cells can be formed in higher voltage system blocks. Modules can be assembled and sent to formation area, where connected in series to achieve a higher total voltage (e.g., 500 V). However, any intermediate voltage may be selected based on building, safety, process, grid, or battery formation-test machine needs. Limitations on voltage can also be based on available DC/DC or AC/DC conversion technologies based on cost or conversion efficiencies. A control system for bypassing energy (charge, discharge both) around modules, cells, or packs can ensure safe operation, preventing overcharge and allowing for full formation of each cell. A safety system can monitor temperature, current, and/or voltage to prevent cell damage and thermal runaway due to over-temperature, over-charge or over-discharge.

Embodiments described herein can include algorithms to detect cell level failure, internal shorts, and other failure modes using sensors. Sensing can be used to sense or determine cell voltage, temperature, current, module level voltage, module level temperature, module level current, pack level voltage, pack level temperature, and/or pack level current. Algorithms can then be used to diagnose the functional status of each cell in the system. In some cases, sensing can be accomplished via a battery management system (BMS), test system sensing, secondary sensing systems, or any combination thereof. Safety systems can include area temperature (hot spot), fire detection, smoke detection, hydrogen detection, carbon monoxide (CO) detection, carbon dioxide (CO₂) detection, volatile organic compound (VOC) detection, or other detection methods to ensure the systems are not damaged or to prevent damage to the system, batteries and facilities during formation. Safety systems can include fire suppression systems to prevent facility damage, active venting systems to prevent facility damage and personal injury, and protection systems to provide propagation protection between cells, modules, and/or battery packs under formation.

In some embodiments, an energy storage system can store and circulate power to and from formation systems. In some embodiments, the energy storage system can include a storage device. In some embodiments, the energy storage system can distribute DC power at a building or campus level. The energy storage system can also reduce parasitic losses due to transformers, power factor correction systems, and/or other AC components. A dual use of an energy storage system as a facility backup for critical systems is also applicable. In some embodiments, the energy storage system can function as a dry room backup to protect WIP from damage due to a loss of system power. In some embodiments, an energy system can include bi-directional power conversion between AC and DC in order to share power to and from a building grid, either in front of or behind an electrical meter. In some embodiments, an energy storage system can include bi-directional power conversion between AC and DC in order to share power to and from the building grid in a secondary or remote location to control the total power conversion at a campus or grid scale. In some embodiments, an energy storage system can include a bi-directional power conversion between AC and DC in order to share power to and from the building grid in a secondary or remote location to control total power conversion at a facility, multiple facilities, a campus, a micro grid, and/or a macro grid in order to create a secondary AC grid for power distribution.

In some embodiments, an energy storage system can include a bi-directional power conversion between DC and DC in order to share power to and from the formation system without additional AC conversion loss. In some embodiments, the energy storage system can include a bi-directional power conversion between DC and DC in order to share power to create a common DC power distribution within a single facility. In some embodiments, an energy storage system can include bi-directional power conversion between DC and DC in order to share power to create a common DC power distribution between two or more facilities. In some embodiments, an energy storage system can include bi-directional power conversion between DC and DC in order to share power to create a common DC distribution at a campus, a micro grid, or a macro grid level. In some embodiments, renewable power can provide energy to make up for conversion losses in the formation system, generating an off-grid formation system or a low power formation system.

In some embodiments, an energy storage system can include a grid or renewable connection for metering energy to the formation system and providing energy to account for efficiency losses. In some embodiments, an energy storage system with building controls can monitor power needs throughout the facility and campus to provide demand load, frequency regulation, peak shaving, load leveling, and/or other grid firming operations. In some embodiments, an energy storage system can serve a formation system and/or other secondary renewable uses, such as charging station power for plug-in-hybrid-electric vehicles (PHEV's), electric vehicles (EV's), or any other suitable implementations.

Monitoring voltage at various points throughout cells or electrodes can be an important aspect of building an energy storage system. Differences in voltage gradients or inflection points can help identify problematic cells or electrodes. Identifying these faulty elements during production or even during operation can significantly limit the downtime of the energy storage system during repair or replacement.

In some embodiments, electrodes described herein can include conventional solid electrodes. In some embodiments, the solid electrodes can include binders. In some embodiments, electrodes described herein can include semi-solid electrodes. Semi-solid electrodes described herein can be made: (i) thicker (e.g., greater than 100 μm-up to 2,000 μm or even greater) due to the reduced tortuosity and higher electronic conductivity of the semi-solid electrode, (ii) with higher loadings of active materials, and (iii) with a simplified manufacturing process utilizing less equipment. These relatively thick semi-solid electrodes decrease the volume, mass and cost contributions of inactive components with respect to active components, thereby enhancing the commercial appeal of batteries made with the semi-solid electrodes. In some embodiments, the semi-solid electrodes described herein are binderless and/or do not use binders that are used in conventional battery manufacturing. Instead, the volume of the electrode normally occupied by binders in conventional electrodes, is now occupied by: 1) electrolyte, which has the effect of decreasing tortuosity and increasing the total salt available for ion diffusion, thereby countering the salt depletion effects typical of thick conventional electrodes when used at high rate, 2) active material, which has the effect of increasing the charge capacity of the battery, or 3) conductive additive, which has the effect of increasing the electronic conductivity of the electrode, thereby countering the high internal impedance of thick conventional electrodes. The reduced tortuosity and a higher electronic conductivity of the semi-solid electrodes described herein, results in superior rate capability and charge capacity of electrochemical cells formed from the semi-solid electrodes. Since the semi-solid electrodes described herein, can be made substantially thicker than conventional electrodes, the ratio of active materials (i.e., the semi-solid cathode and/or anode) to inactive materials (i.e., the current collector and separator) can be much higher in a battery formed from electrochemical cell stacks that include semi-solid electrodes relative to a similar battery formed form electrochemical cell stacks that include conventional electrodes. This substantially increases the overall charge capacity and energy density of a battery that includes the semi-solid electrodes described herein.

In some embodiments, the electrode materials described herein can be a flowable semi-solid or condensed liquid composition. In some embodiments, the electrode materials described herein can be binderless or substantially free of binder. A flowable semi-solid electrode can include a suspension of an electrochemically active material (anodic or cathodic particles or particulates), and optionally an electronically conductive material (e.g., carbon) in a non-aqueous liquid electrolyte. Said another way, the active electrode particles and conductive particles are co-suspended in an electrolyte to produce a semi-solid electrode. Examples of battery architectures utilizing semi-solid suspensions are described in U.S. Patent Publication No. 2022/0238923 (“the '923 publication”), filed Jan. 21, 2022 and titled “Production of Semi-Solid Electrodes Via Addition of Electrolyte to Mixture of Active Material, Conductive Material, and Electrolyte Solvent,” and U.S. patent application Ser. No. 18/212,414 (“the '414 application”), filed Jun. 21, 2023 and titled “Electrochemical Cells with High-Viscosity Semi-solid Electrodes, and Methods of Making the Same,” the entire disclosures of which are hereby incorporated by reference.

In some embodiments, power management systems described herein can include any of the aspects described in U.S. Pat. No. 10,153,651 (“the '651 patent”), filed Oct. 9, 2015, and titled, “Systems and Methods for Battery Charging,” the disclosure of which is hereby incorporated by reference in its entirety. In some embodiments, battery management systems described herein can include any of the aspects described in U.S. patent application Ser. No. 17/743,631 (“the '631 application”), filed Nov. 20, 2020, and titled, “Electrochemical Cells Connected in Series in a Single Pouch and Methods of Making the Same,” the disclosure of which is hereby incorporated by reference in its entirety.

As used in this specification, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

The term “substantially” when used in connection with “cylindrical,” “linear,” and/or other geometric relationships is intended to convey that the structure so defined is nominally cylindrical, linear or the like. As one example, a portion of a support member that is described as being “substantially linear” is intended to convey that, although linearity of the portion is desirable, some non-linearity can occur in a “substantially linear” portion. Such non-linearity can result from manufacturing tolerances, or other practical considerations (such as, for example, the pressure or force applied to the support member). Thus, a geometric construction modified by the term “substantially” includes such geometric properties within a tolerance of plus or minus 5% of the stated geometric construction. For example, a “substantially linear” portion is a portion that defines an axis or center line that is within plus or minus 5% of being linear.

As used herein, the term “set” and “plurality” can refer to multiple features or a singular feature with multiple parts. For example, when referring to a set of electrodes, the set of electrodes can be considered as one electrode with multiple portions, or the set of electrodes can be considered as multiple, distinct electrodes. Additionally, for example, when referring to a plurality of electrochemical cells, the plurality of electrochemical cells can be considered as multiple, distinct electrochemical cells or as one electrochemical cell with multiple portions. Thus, a set of portions or a plurality of portions may include multiple portions that are either continuous or discontinuous from each other. A plurality of particles or a plurality of materials can also be fabricated from multiple items that are produced separately and are later joined together (e.g., via mixing, an adhesive, or any suitable method).

As used herein, the term “semi-solid” refers to a material that is a mixture of liquid and solid phases, for example, such as a particle suspension, a slurry, a colloidal suspension, an emulsion, a gel, or a micelle.

As used herein, the terms “activated carbon network” and “networked carbon” relate to a general qualitative state of an electrode. For example, an electrode with an activated carbon network (or networked carbon) is such that the carbon particles within the electrode assume an individual particle morphology and arrangement with respect to each other that facilitates electrical contact and electrical conductivity between particles and through the thickness and length of the electrode. Conversely, the terms “unactivated carbon network” and “unnetworked carbon” relate to an electrode wherein the carbon particles either exist as individual particle islands or multi-particle agglomerate islands that may not be sufficiently connected to provide adequate electrical conduction through the electrode.

As used herein, the terms “energy density” and “volumetric energy density” refer to the amount of energy (e.g., MJ) stored in an electrochemical cell per unit volume (e.g., L) of the materials included for the electrochemical cell to operate such as, the electrodes, the separator, the electrolyte, and the current collectors. Specifically, the materials used for packaging the electrochemical cell are excluded from the calculation of volumetric energy density.

As used herein, the terms “high-capacity materials” or “high-capacity anode materials” refer to materials with irreversible capacities greater than 300 mAh/g that can be incorporated into an electrode in order to facilitate uptake of electroactive species. Examples include tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

As used herein, the term “composite high-capacity electrode layer” refers to an electrode layer with both a high-capacity material and a traditional anode material, e.g., a silicon-graphite layer.

As used herein, the term “solid high-capacity electrode layer” refers to an electrode layer with a single solid phase high-capacity material, e.g., sputtered silicon, tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

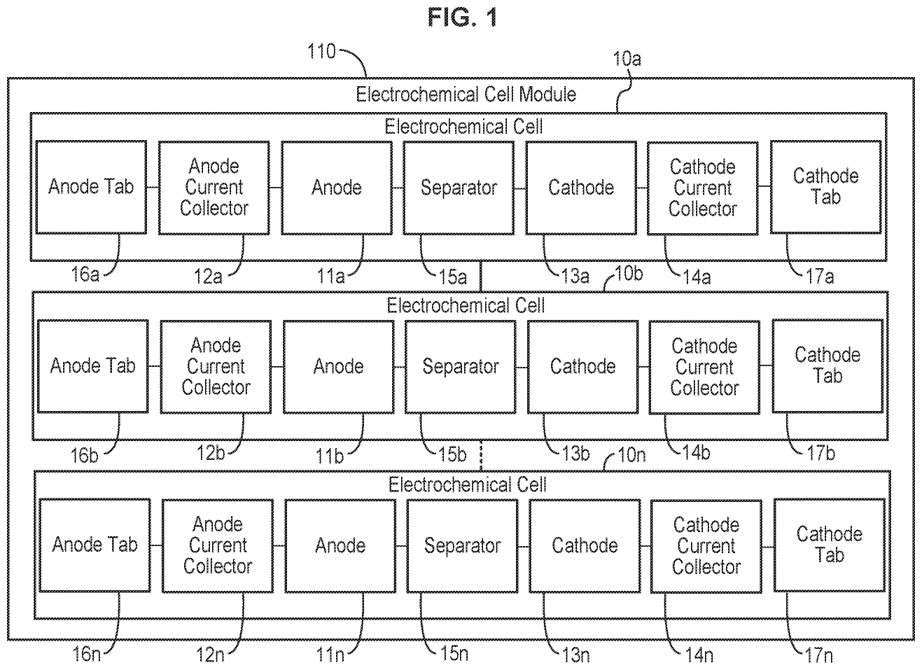

FIG. 1 shows a block diagram of an electrochemical cell module 110 (hereinafter “battery module”), according to an embodiment. As shown, the battery module 110 includes electrochemical cells 10a, 10b,- . . . 10n electrically connected in series. Each electrochemical cell includes an anode material 11a, 11b,- . . . 11n disposed on an anode current collector 12a, 12b,- . . . 12n, a cathode material 13a, 13b,- . . . 13n disposed on a cathode current collector 14a, 14b,- . . . 14n, and a separator 15a, 15b,- . . . 15n disposed between the anode material 11a-11n and the cathode material 13a-13n. In some embodiments, the anode material 11a-11n and/or the cathode material 13a-13n can include a semi-solid electrode material, as described above. In some embodiments, the battery module 110 can include individual electrochemical cells, modules (e.g., a plurality of individual electrochemical cells electrically connected, for example, in series or parallel), or a battery pack (e.g., a plurality of modules that are connected, for example, in series or parallel). In some embodiments, the battery module 110 can include a plurality of electrochemical cells for charging and discharging.

Electrochemical cells and electrochemical cell modules typically undergo formation, which involves an initial round of charging and discharging, as part of the manufacturing process. Battery formation systems (hereinafter “formation systems”) are systems or apparatuses for forming electrochemical cells. A formation system typically resides in a battery manufacturing facility, the battery manufacturing facility including a variety of other amenities for battery manufacturing such as, for example, electrochemical cell assembly lines, manufacturing rooms, dry rooms, heating, ventilation, and air conditioning (HVAC) systems for cooling, equipment for moving supplies, etc. On a higher level, a battery manufacturing campus (hereinafter “campus”) can include an aggregate of battery manufacturing facilities and other resources useful for battery manufacturing, but is not limited to battery manufacturing. Streamlined transfer of energy between elements at the formation system level, the manufacturing facility level, and the campus level is important for significantly reducing costs and materials and improving overall efficiency of manufacturing.

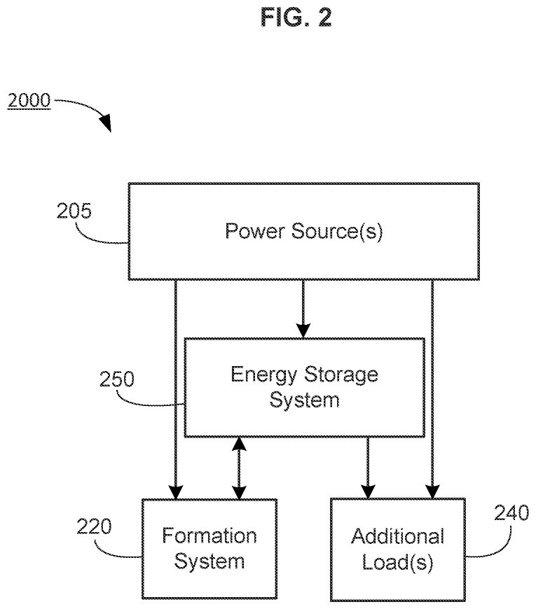

FIG. 2 shows a schematic block diagram of energy transfer within a campus 2000, according to an embodiment. As shown in FIG. 2, one or more power sources transfer energy to an energy storage system 250. The energy storage system 250 may be configured to either (1) store the energy received for later use; (2) transfer the energy to a formation system 220; or (3) transfer energy to additional loads 240 that may be associated with electrochemical cell manufacturing. The power sources 205 may transfer energy directly to the formation system 220 or directly to the additional loads 240. Although not shown, the energy storage system 250, the formation system 220, and the additional loads 240 may reside in a facility. In some embodiments, the formation system 220 may be configured to transfer energy back to the energy storage system 250 for later use or for backup energy for the facility.

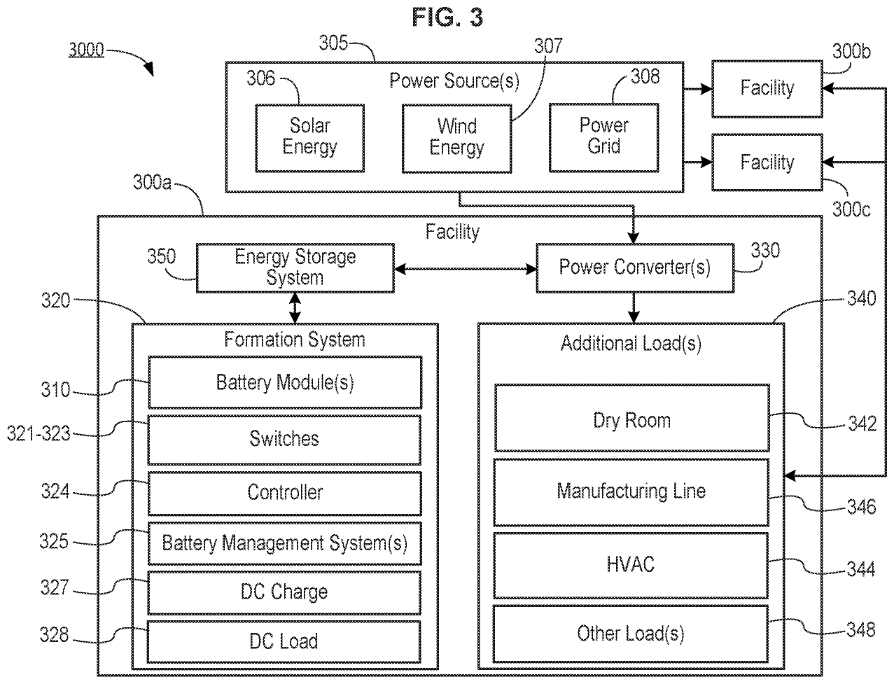

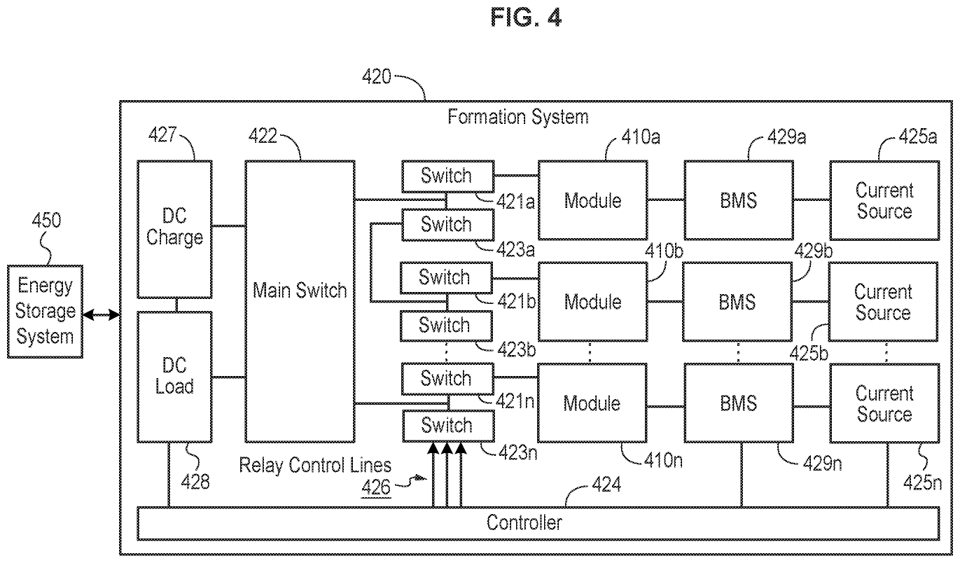

FIG. 3 shows schematic block diagram of energy transfer within a battery manufacturing campus, according to an embodiment. As shown in FIG. 3, facilities 300a, 300b, 300c are configured to receive energy from power sources 305. The power sources 305, the formation system 320, the additional loads 340, and the energy storage system 350 may be substantially similar in function and/or structure to the power sources 205, the formation system 220, the additional loads 240, and the energy storage system 250 and therefore certain aspects of the power sources 305, the formation system 320, the additional loads 340, and the energy storage system 350 will not be described with respect to FIG. 3. The power sources 305 may include solar energy 306, wind energy 307, and/or power grid energy 308. In some embodiments, the facilities 300a, 300b, 300c may be configured to receive energy from other power sources. In some embodiments, facility 300b and facility 300c may include the same amenities and/or equipment as facility 300. In some embodiments, facility 300b and 300c may include different amenities and/or equipment and may be used for a different purpose than facility 300a. As shown, energy is transferred from the power sources 305 to one or more power converters 330 in facility 300a. The power converters 330 may be DC/DC power converters to step incoming voltage to a desired level, such as for battery formation. In particular, the facilities 300a-300c may include DC/DC converters for converting solar energy into a desired voltage used to charge battery modules 310. In some embodiments, AC/DC power converters are included to convert AC power coming from the wind energy source 307 and/or the power grid energy source 308. After conversion, DC energy is either transferred to the energy storage system 350 where it is stored, or the DC energy is directly transferred to additional loads 340 including a dry room 342, a manufacturing line 346, HVAC 344, and/or other loads 348 as needed. The energy storage system 350 and a formation system 320 are configured to transfer DC energy bidirectionally via a DC electrical connection depending on the needs of the facility 300a. When the battery modules 310 are charging, the battery modules 310 act as a load to the energy storage system 350, as power flows from the energy storage system 350 to the battery modules 310. When the battery modules 310 are discharging, the energy flows into the energy storage system 350, which is then charging relative to the battery modules 310. During discharge of the battery modules 310, the formation system 320 is configured to transfer DC energy back to the energy storage system 350 for storage via a DC connection to the DC load 328 rather than discharging excess charge through resistors, which results in loss of energy via heat. The formation system 320 includes battery management systems 325 and switches 321-323 electrically connected to the battery modules 310 to control flow of current through the battery modules 310 via a controller 324, explained in further detail below with respect to FIG. 4. In some embodiments, the DC load 328 and a DC charge 327 can be connected in parallel to the formation system 320.

In some embodiments, the energy storage system 350 may provide energy for a facility, a campus, or a macro grid level DC supply with a low voltage (i.e., a voltage of about 0V to about 100 V). The energy storage system 350 may provide a voltage supply of no more than about 400 V, no more than about 350 V, no more than about 300 V, no more than about 250 V, no more than about 200 V, no more than about 150 V, no more than about 100 V, no more than about 95 V, no more than about 90 V, no more than about 85 V, no more than about 80 V, no more than about 75 V, no more than about 70V, no more than about 65 V, no more than about 60 V, no more than about 55 V, no more than about 50 V, no more than about 45 V, no more than about 40 V, no more than about 35 V, no more than about 30 V, no more than about 25 V, no more than about 20 V, no more than about 15 V, or no more than about 10 V.

In some embodiments, the energy storage system 350 may provide energy for a facility, a campus, or a macro grid level DC supply with a high voltage (a voltage of greater than about 250V). The energy storage system 250 may provide a voltage supply of at least about 200V, at least about 250 V, at least about 300 V, at least about 350 V, at least about 400 V, at least about 410 V, at least about 420 V, at least about 430 V, at least about 440 V, at least about 450 V, at least about 460 V, at least about 470 V, at least about 480 V, at least about 490 V, at least about 500 V, at least about 510 V, at least about 520 V, at least about 530 V, at least about 540 V, at least about 550 V, at least about 600 V, at least about 700 V, or at least about 800 V.

In some embodiments, the energy storage system 350 may allocate energy stored (such as excess energy generated by formation of the battery modules 310) to power one or more of the additional loads 340. With this energy storage system 350, DC energy is stored, which reduces the number of transformers used in the facility 300a, thereby reducing overall energy consumption. In other words, the energy storage system 350 may transfer DC energy to the formation system 320 without an AC transformer. The energy storage system may receive and store energy from renewable or sustainable power sources, reducing a total grid power requirement to enable lower cost renewable energy offset and to mitigate carbon footprint of the total grid. In addition, the facilities 300a-c may operate by pulling less energy at a given time from the power grid. Energy loss from AC/DC conversion increases when a larger starting voltage is converted; therefore, reducing the voltage transferred to the facilities 300a-300c at a given time reduces energy lost due to AC/DC conversion, thereby reducing overall energy consumption of the facility and campus.

FIG. 4 shows a diagram of an electrochemical cell stack formation system, according to an embodiment. The energy storage system 450 and the formation system 420 may be substantially similar in function and/or structure to the energy storage system 250, 350 and the formation system 220, 320, and therefore certain aspects of the energy storage system 450 and the formation system 420 will not be described with respect to FIG. 4. As shown, the energy storage system 450 transfers DC energy to the formation system 420 via a DC electrical connection to the DC charge 427. In some embodiments, the DC charge is configured to receive a signal (e.g., via an electrical connection) from the controller 424 to draw a desired amount of current into the formation system 420. The DC charge 427 is electrically connected in series to a main switch 422. The main switch 422 allows current flow through the battery modules 410a, 410b,- . . . 410n when in a first configuration and blocks current from flowing through the battery modules 410a-410n when in a second configuration. The main switch 422 may transition from the first configuration (Closed, or ON) to the second configuration (Open or OFF) in response to a signal from the controller 424 via relay control lines 426.

The formation system 420 may also include switches 421a, 421b,- . . . 421n, 423a, 423b,- . . . 423n (e.g., contactors, relays, transistors, etc.), corresponding to each battery module 410a-n and configured to control the current through each battery module 410a, 410b,- . . . 410n. For example, a first switch 421a may be connected in series with a first battery module 410a and a second switch 423a may be connected in parallel with the first battery module 410a such that when the first switch 421a is closed and the second switch 423a is open, current moves through the first battery module 410a towards subsequent battery modules 410b-n in series. In contrast, when the first switch 421a is open and the second switch 423a is closed, current is directed away from the first battery module 410a and to different battery modules 410b-n in the formation system that may need charging. In some embodiments, both the first switch 421a and the second switch 423a may be closed such that current is blocked from flowing through the first battery module 410a and any subsequent battery modules 410b-n in series. In some embodiments, both the first switch 421a and the second switch 423a may be open such that current may flow through the first battery module 410a as well as subsequent battery modules 410b-n in series. The switches 421a-n, 422a-n may switch between an open configuration and a closed configuration in response to a signal from the controller 424 via relay control lines 426. The battery modules 410a-n are each connected to a battery management system 429a, 429b,- . . . 429n for monitoring voltage and battery health of the battery module. The battery management system 429a-n is coupled to a current source 425a, 425b,- . . . 425n to control the current through the respective battery module 410a-n. While the switches 421-423 are shown in this configuration, the switches 421-423 may be arranged in any suitable arrangement such that current flow may be directed away from a battery module 410 if needed.

The arrangement of switches 421a-n, 423a-n, allows for the removal of faulty battery modules 410a-n from the flow path of current such that formation of healthy battery modules may continue, thereby increasing formation efficiency. Additionally, fully charged battery modules may be removed from the flow path of current if needed. For example, the controller 424 may detect a faulty battery module 410a-n from voltage measurements received from the battery management system 429a-n. The controller 424 in turn may send a signal to open the first switch 421a-n such that current is blocked from flowing through the faulty battery module, and instead moves directly to the second battery module 410a-n. The controller 424 may also sense (via the battery management system 429a-n) that one of the battery modules 410a-n no longer needs to charge. The controller 424 may then send a signal to configure the switches 421a-n, 423a-n such that charge is drawn from the charged battery module and redirected toward a different battery module 410a-n that needs charge. In some embodiments, the formation system 420 blocks current flow through a faulty battery module 410a-n automatically. In some embodiments, the formation system 420 blocks current flow through a fully charged battery module 410a-n automatically. In some embodiments, the formation system 420 draws current from a fully charged battery module 410a-n automatically. Energy may be transferred out of the formation system 420 via a DC electrical to the DC load 428 back to the energy storage system 450.

In some embodiments, the formation system 420 can include a range of about 1 to about 1000 battery modules 410. In some embodiments, the formation system 420 can include at least about 2, at least about 3, at least about 4, at least about 5, at least about 6, at least about 7, at least about 8, at least about 9, at least about 10, at least about 20, at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, or at least about 900 battery modules 410. In some embodiments, the formation system 420 can include no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3 battery modules 410. Combinations of the above-referenced numbers of battery modules 410 are also possible (e.g., at least about 2 and no more than about 1,000 or at least about 4 and no more than about 50), inclusive of all values and ranges therebetween. In some embodiments, the formation system 420 can include about 2, about 3, about 4, about 5, about 6, about 7, about 8, about 9, about 10, about 20, about 30, about 40, about 50, about 60, about 70, about 80, about 90, about 100, about 200, about 300, about 400, about 500, about 600, about 700, about 800, about 900, or about 1,000 battery modules 420.

In some embodiments, the formation system 420 can include a range of about 1 to about 1000 battery management systems 429. In some embodiments, the formation system 420 may include a range of about 1 to about 1000 current sources 425. In some embodiments, the formation system 420 has the same number of battery management systems 429 as battery modules 410. In some embodiments, the formation system 420 has the same number of current sources 425 as battery modules 410. In some embodiments, the formation system 420 may include a range of about 1 to about 3000 switches 421, 422, 423. In some embodiments, the formation system 420 can include at least about 2, at least about 4, at least about 6, at least about 8, at least about 10, at least about 20, at least about 40, at least about 60, at least about 80, at least about 100, at least about 200, at least about 400, at least about 600, at least about 800, at least about 1000, at least about 2000, at least about 2200, at least about 2400 switches 421, 422, 423. In some embodiments, the formation system 620 can include no more than about 3000, no more than about 2400, no more than about 2200, no more than about 2000, no more than about 1000, no more than about 800, no more than about 600, no more than about 400, no more than about 200, no more than about 100, no more than about 80, no more than about 60, no more than about 40, no more than about 20, no more than about 10, no more than about 8, no more than about 6, or no more than about 4 switches 421, 422, 423. Combinations of the above-referenced numbers of battery switches 421, 422, 423 are also possible (e.g., at least about 2 and no more than about 1,000 or at least about 4 and no more than about 50), inclusive of all values and ranges therebetween.

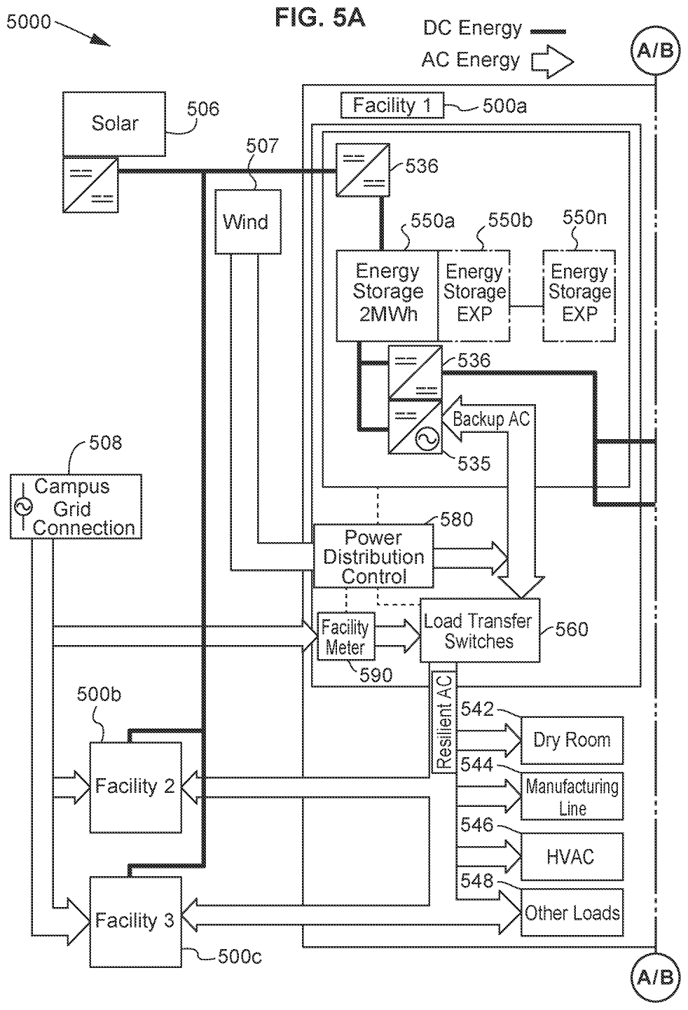

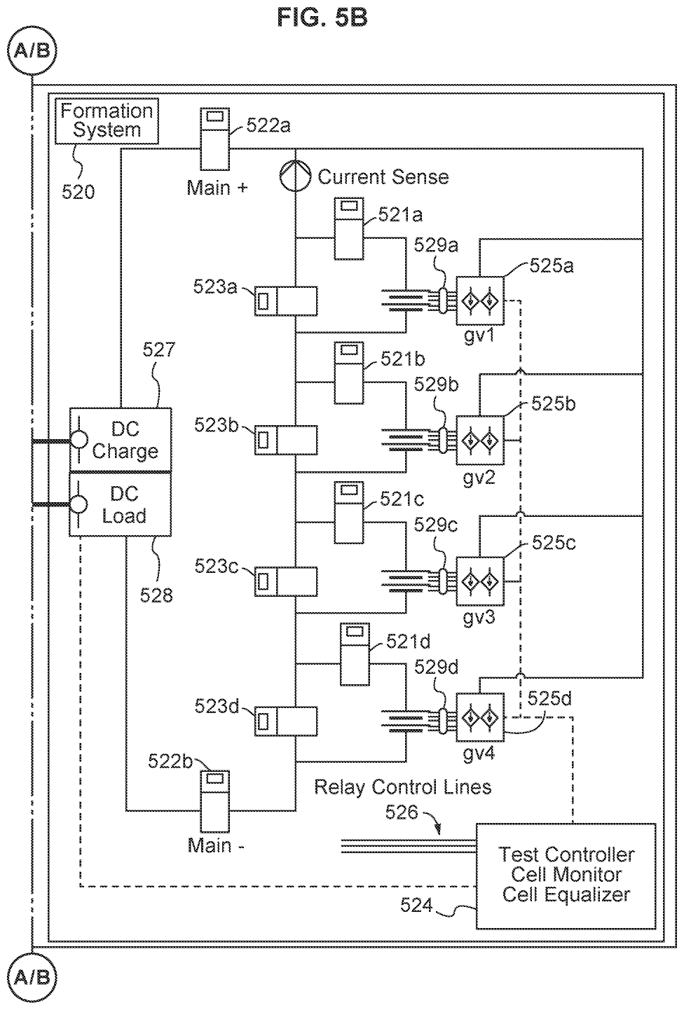

FIGS. 5A-5B show diagrams of battery manufacturing campus including an energy storage system, according to an embodiment. The facilities 500a, 500b, 500c; the power sources 506, 507, 508; the formation system 520; the additional loads 542, 544, 546, 548; and the energy storage system(s) 550 may be substantially similar in function and/or structure to the power sources 205, 305; the formation system 220, 320, 420; the additional loads 240, 340; and the energy storage system 250, 350, 450, and therefore certain aspects of the facilities 500a, 500b, 500c; the power sources 506, 507, 508; the formation system 520; the additional loads 542, 544, 546, 548; and the energy storage system 550 will not be described with respect to FIGS. 5A-5B.

As shown, a solar power generator 506 delivers DC energy to the facilities 500a, 500b, 500c. Facility 500a includes one or more energy storage systems 550a, 550b,- . . . 550n (collectively referred to as energy storage systems 550), which may transfer energy through a DC/DC power converter 536 to a DC charge 527, which delivers current to a formation system 520. As shown, the formation system 520 includes four battery modules 510a, 510b, 510c, 510d connected in series and electrically coupled to respective battery management systems 529a, 529b, 529c, 529d and current sources 525a, 525b, 525c, and 525d. The formation system 520 includes main switches 522a and 522b as well as switches 521a, 521b, 521c, 521d and switches 523a, 523b, 523c, 523d controlled by a controller 524 and relay control lines 526. The battery modules 510a-d, the battery management system 520a-d, the current sources 525a-d, the main switches 522a-b, the switches 521a-d and 523a-d, the controller 524, and the relay control lines 526 may be substantially similar in function and/or structure to the battery modules 410a-n, the battery management system 420a-n, the current sources 425a-n, the main switch 422, the switches 421a-d and 423a-n, the controller 424, and the relay control lines 426, and therefore certain aspects of the battery modules 510a-d, the battery management system 520a-d, the current sources 525a-d, the main switches 522a-b, the switches 521a-d and 523a-d, the controller 524, and the relay control lines 526 will not be described with respect to FIGS. 5A-5B.

In some embodiments, the solar energy generator may transfer energy into the power distribution control station 580. As shown, a wind power generator 507 transfers energy to a power distribution control station 580. The energy from the wind power generator 507 may either be transferred (1) from the power distribution control center 580 through load transfer switches 560 to power additional loads of the facility 500a including a dry room 542, a manufacturing line 544, an HVAC system 546, or other loads 548; or (2) through an AC/DC power converter 535 to the energy storage systems 550 for later use. A campus grid connection 508 may provide energy to facilities 500a-c. In facility 500a, the energy from the campus grid connection 508 is transferred through a facility meter 590 and then through load transfer switches 560. The energy may then be either (1) used to power the additional loads; or (2) sent through the AC/DC power converter 535 and stored in the energy storage systems 550 for later use. If backup AC energy (i.e., resilient AC) is needed to power the additional loads, energy stored in the energy storage systems 550 may be transferred through a DC/AC converter 535, to the load transfer switches 560, and then to the additional loads. The resilient AC may also be transferred to the other facilities in the campus 500b, 500c if needed. The power distribution control center 580, the facility meter 590, the load transfer switches 560, and the energy storage systems 550 may be configured to communicate to regulate energy flow throughout the campus 5000.

The load transfer switches 560 include AC transformers. Because the formation system 520 is powered by DC energy stored in the energy storage systems 550, the load transfer switches 560 may include less AC transformers. For instance, the facility 500a may only include the AC transformers needed to support the dry room 542, the manufacturing line 544, the HVAC system 546, and/or other loads 548. Therefore, the facility 500a may include a lower number of AC transformers, which lowers the overall energy consumption of the facility 500a. In some embodiments, the facilities 500b and 500c may also include an energy storage system that allows for use of fewer AC transformers.

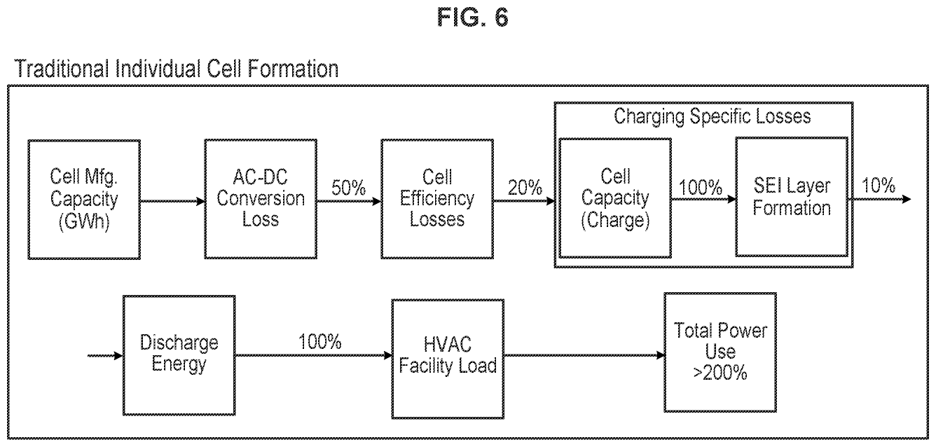

FIG. 6 shows a diagram of a station for a traditional formation of an electrochemical cell. As shown, energy losses are incident upon the cell via AC/DC conversion losses, cell efficiency losses, discharge energy, cell charging, and SEI layer formation. The cell manufacturing capacity represents the energy drawn for formation of the electrochemical cell and can be measured in gigawatt hours (GWh). Each GWh of the electrochemical cell's capacity should be charged with a GWh of energy. In the system shown, all energy needed for formation of the electrochemical cell is transferred through an AC/DC power converter and converted, which results in an energy usage of about 50% of the electrochemical cell's capacity. Energy loss also occurs due to cell efficiency losses. Energy loss due to cell efficiency is typically about 20% of the electrochemical cell's capacity. Some energy losses are specific to charging, including cell capacity (e.g., cell charge) and SEI layer formation. When charging the electrochemical cell in this system, the entirety of the energy comes from the power grid, meaning about 100% of the electrochemical cell's capacity is used. SEI layer formation causes loss of energy through ion consumption, which results in loss of about 10% of the electrochemical cell's capacity. During discharge of the electrochemical cell, about 100% of the electrochemical cell's capacity is expelled (during a complete discharge). Because of waste heat produced during discharge, energy is used to power an HVAC system to cool the facility to a suitable temperature. The additional energy loss incurred from running the HVAC system can be calculated by using the equation f(x)=0.3x, where x represents the total discharge energy. In some embodiments, energy loss incurred from running the HVAC system may vary depending on environmental factors such as ambient temperature. Overall, the traditional station for formation of the electrochemical cell results in a total power usage of at least about 200% of the electrochemical cell's capacity.

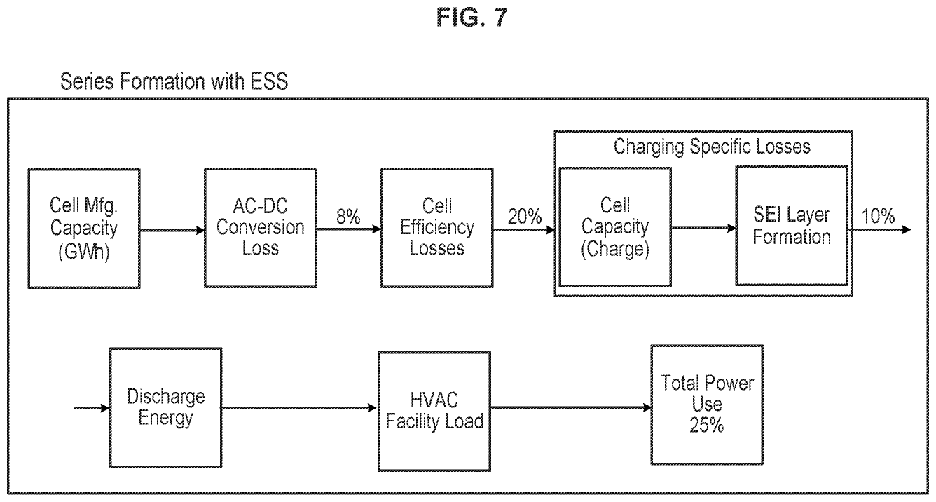

FIG. 7 shows a diagram of a series formation of electrochemical cells with an energy storage system and a formation system, according to an embodiment. In the system shown, charging and discharging of the electrochemical cells relies on energy stored in the energy storage system rather than from the power grid, meaning that energy loss due to charge/discharge reduces to about 0% of each electrochemical cell's capacity. Additionally, because DC energy is used directly, energy loss due to AC/DC conversion is reduced to about 8% of each electrochemical cell's capacity. Therefore, with this system only about 25% of each electrochemical cell's capacity is used during formation. In some embodiments, use of the energy storage system reduces energy loss due to running the HVAC system because energy from discharging the electrochemical cells is transferred back to the energy storage system for storage rather than dissipating as heat.

In some embodiments, energy losses from the formation of electrochemical cells are reduced by at least about 50%, at least about 75%, at least about 100%, at least about 125%, at least about 150%, at least about 175%, at least about 200%, at least about 225%, or at least about 250% of a full capacity of each electrochemical cell, as compared to the formation of an individual electrochemical cell.

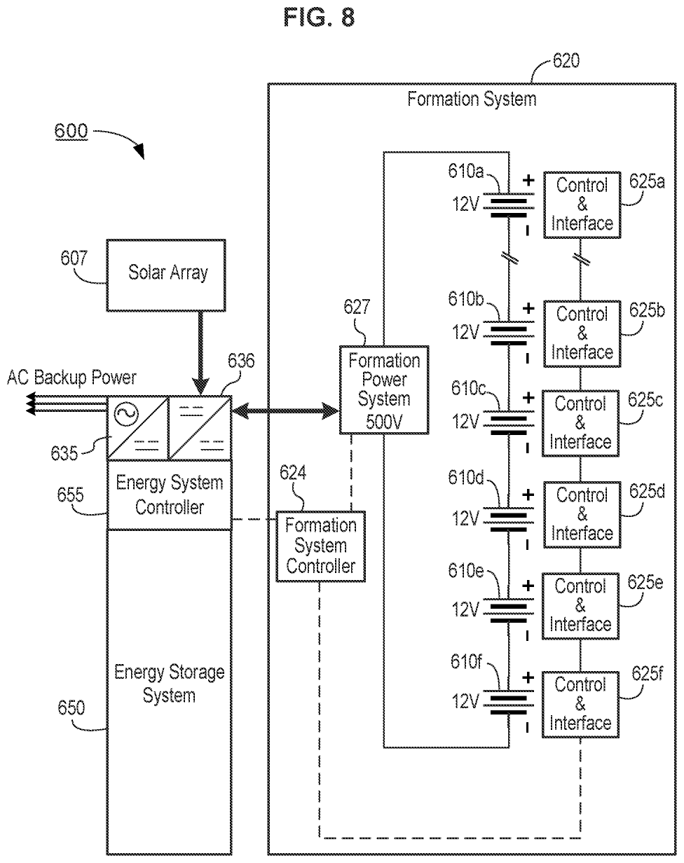

FIG. 8 shows the interaction between a solar array 607, an energy storage system 650, and a formation power system 627, according to an embodiment. As shown, the energy storage system 650 receives DC energy input from the solar array 607 through a DC/DC converter 636. The formation power system 627 receives energy from the energy storage system 650 through the DC/DC converter 636. The formation system can be electrically coupled to the energy storage system 650. The energy storage system 650 includes an energy system controller 655 to regulate the transfer of energy between the energy storage system 650 and the formation power system 627. The energy storage system controller 655 and the formation system controller 624 may communicate directly to control the transfer of energy therebetween. The formation system 620 may include a formation power system 627 electrically connected to a collection of electrochemical cell modules 610a, 610b, 610c, 610d, 610e, 610f connected in series. The electrochemical cell modules 610a-f may be controlled via a formation system controller 624. Each electrochemical cell module 610a-f is coupled to a control and interface system 625a, 625b, 625c, 625d, 625e, 625f used to control current flow through the electrochemical cell modules 610a-f during charge and discharge. The control and interface systems 625a-f may be structurally and/or functionally similar to the battery management systems 425a-n, 525a-d; the switches 421a-n, 521a-d, 422, 522a-b, 423a-n, 523a-d, and/or the current sources 429a-n, 529a-d, as described above with respect to FIG. 4 and FIGS. 5A-5B, and therefore the control and interface systems 625a-f are not described further herein. Although the transfer voltage between the energy storage system 650 and the formation power system 627 is shown as 500V, the transfer voltage can be any suitable voltage for formation of the electrochemical cells 625a-f. In some embodiments, the transfer voltage between the energy storage system 650 and the formation power system 627 can be at least about 200 V, at least about 250 V, at least about 300 V, at least about 350 V, at least about 400 V, at least about 450 V, or at least about 500 V, inclusive of all values and ranges therebetween.

In some embodiments, the energy storage system 650 can provide building power backup energy. As shown, the energy storage system 650 can transfer energy through a DC/AC converter 635 to provide AC backup energy. In some embodiments, the energy storage system 650 can provide DC backup energy as well.

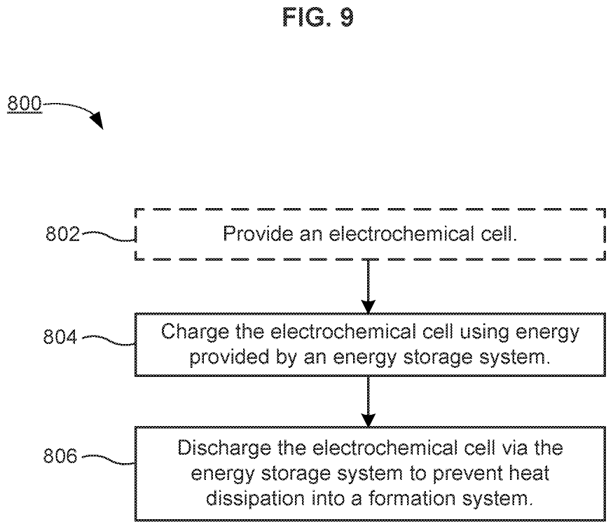

FIG. 9 is a flowchart of a method 800 for forming an electrochemical cell or battery module via an energy storage system, according to an embodiment. At step 802, an electrochemical cell is provided for formation. In some embodiments, a battery module including a plurality of electrochemical cells in series may be used. The electrochemical cell is charged using energy provided by an energy storage system, at step 804. At step 806, the electrochemical cell is discharged via the energy storage system to prevent heat dissipation into a formation system. In some embodiments, the charge leaving the electrochemical cell during discharge may be used to directly charge other electrochemical cells or battery modules connected in series.

In some embodiments, the electrochemical cell system, the battery module, the energy storage system, and the formation system can be substantially similar to and/or the same as any electrochemical cell, battery module, energy storage system, and formation system described above. Thus, the electrochemical cell, the battery module, the energy storage system, and the formation system are not described in further detail herein.

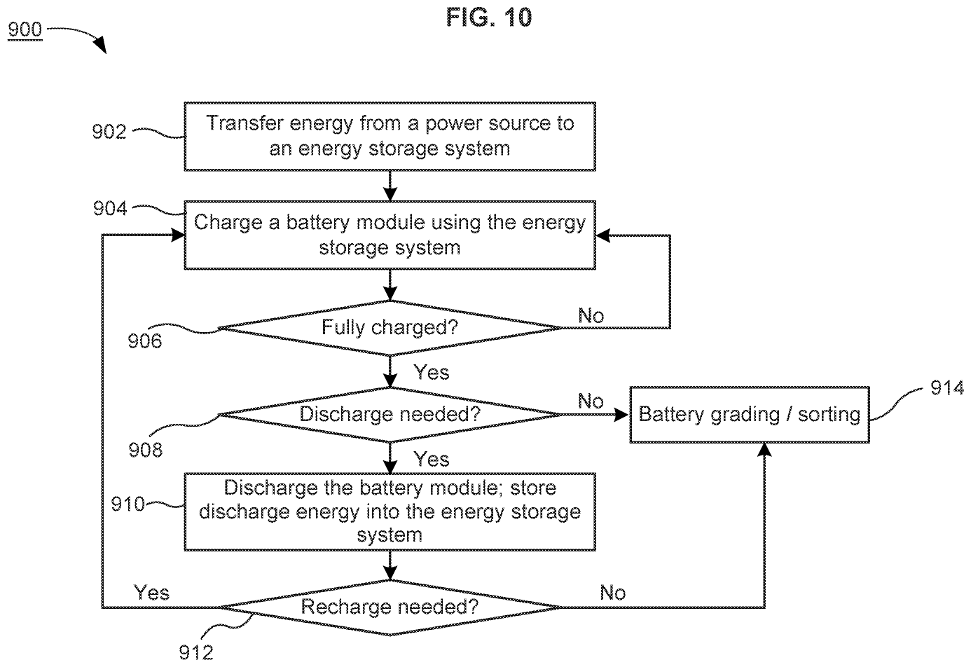

FIG. 10 is a flowchart of a method 900 for forming a battery module via a backup power from an energy storage system, according to an embodiment. In this method 900, a power source is employed to transfer startup energy to an energy storage system, at step 902, to initiate a battery formation procedure. At step 904, the energy storage system charges a battery module or a plurality of battery modules, each of which can include a plurality of batteries. Charging states of the battery module can be monitored and controlled by a controller, therefore allowing the determination of whether the batteries are fully charged, as in step 906. If the batteries are not fully charged, then the energy storage system can continue charging the battery module. If the batteries are fully charged, the controller then determines in step 908 whether battery discharge is needed due to, for example, requirements from battery formation or testing. If discharge is not needed, the fully charged batteries can be conveyed to next steps, such as battery grading or sorting at step 912. If discharge is needed, the batteries can be discharged at step 910, in which the discharged energy is transferred back to the energy storage system. After discharge, the controller can determine at step 912 whether recharge is necessary for battery formation or test, based on, for example, the state of health (SOH) of the batteries. If so, the batteries can be processed again via step 904, in which the energy storage system charges the batteries using the energy from battery discharge in step 910. If battery recharge is not needed, the batteries can be processed via step 914 for grading or sorting. In some embodiments, the controller can be substantially similar to and/or the same as any controller described above. Thus, the controller is not described in further detail herein.

In some embodiments, the power source can transfer energy to the energy storage system during battery charging or discharging. For example, the power source can provide makeup power to the energy storage system if the controller detects that the amount of energy in the energy storage system drops below a threshold. In another example, during discharge, the controller can estimate the amount of energy to be released from discharge and determine whether the amount of energy is sufficient for the next round of battery charging. If not, the controller can direct the power source to transfer supplemental energy to the energy storage system.

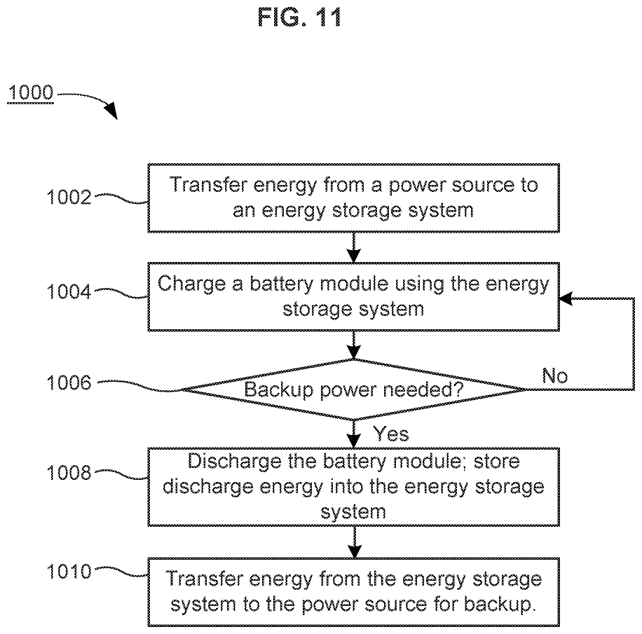

FIG. 11 is a flowchart of a method 1000 for forming a battery module via an energy storage system, according to an embodiment. A power source is employed to transfer energy to an energy storage system, at step 1002, to initiate the charging procedure. The energy storage system can then charge a battery module at step 1004. During charging, a controller can be employed to monitor charging states of the batteries, as well as any control signal from external utilities, at step 1006. If backup power is needed due to, for example, unexpected power outage or low energy production rate of solar power plant (e.g., on cloudy days), the controller can direct the battery module to discharge the batteries and store the discharged energy in the energy storage system, as in step 1008. The energy storage system can then supplement the power source to power external utilities by transferring the stored energy to the power source at step 1010. In some embodiments, battery charging at step 1004 and energy transfer to the power source at step 1010 can occur concurrently, provided that the amount of energy stored in the energy storage system is sufficient. For example, the power source can be a solar plant, which can produce abundant energy during daytime while the demand is relatively low. The power source can store the excess energy into the energy storage system for both battery charging and power backup.

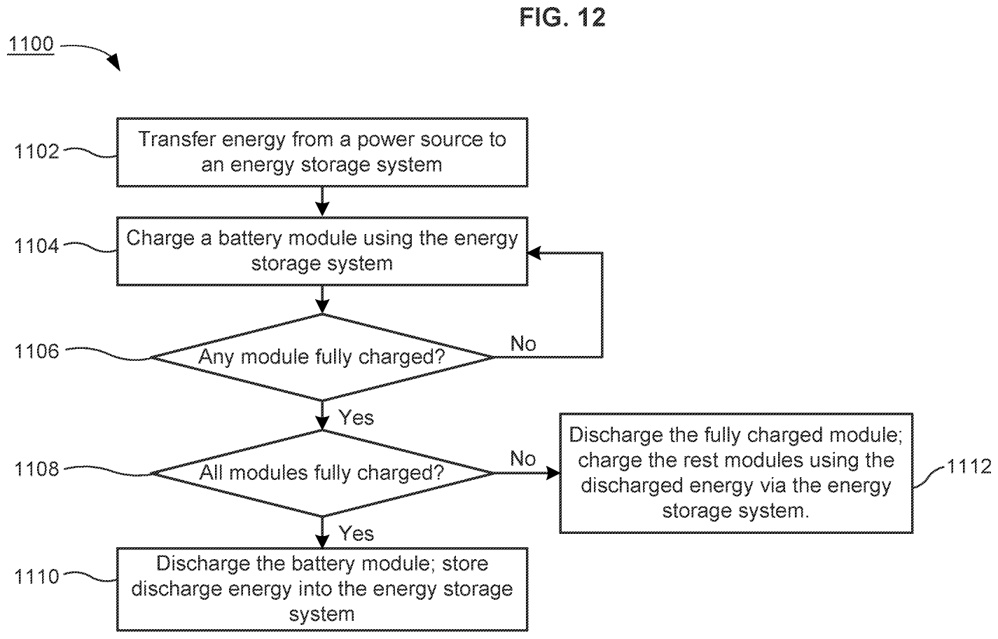

FIG. 12 is a flowchart of a method 1100 for forming a battery module via an energy storage system, according to an embodiment. In this method, a power source is first employed to transfer energy to an energy storage system to initiate the formation procedures at step 1102, followed by the charging of a plurality of battery modules using the energy storage system at step 1104. A controller is employed to monitor charging states of each battery module and determine whether any battery module is fully charged at step 1106. A battery module can be regarded as fully charged when, for example, the voltage is above a preset value. If no fully charged module is found in step 1106, the energy storage system can continue charging the battery modules. On the other hand, if one or more modules are fully charged, the controller then determines whether all modules are fully charged at step 1108. If so, the controller can direct the battery modules to discharge the batteries and store the discharge energy in the energy storage system as in step 1110. If some battery modules are fully charged but not the others, the controller can then direct the battery module to discharge those fully charged battery modules and store the discharge energy in the energy storage system, which can concurrently charge those battery modules that are not fully charged at step 1112. In some embodiments, the controller can selectively discharge and/or charge certain fully charged battery modules at step 1110 and/or step 1112. For example, the controller can monitor the capacity of batteries in each battery module and terminate the charging/discharging cycles for those battery modules that have a capacity greater than a preset value.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

In addition, the disclosure may include other innovations not presently described. Applicant reserves all rights in such innovations, including the right to embodiment such innovations, file additional applications, continuations, continuations-in-part, divisional s, and/or the like thereof. As such, it should be understood that advantages, embodiments, examples, functional, features, logical, operational, organizational, structural, topological, and/or other aspects of the disclosure are not to be considered limitations on the disclosure as defined by the embodiments or limitations on equivalents to the embodiments. Depending on the particular desires and/or characteristics of an individual and/or enterprise user, database configuration and/or relational model, data type, data transmission and/or network framework, syntax structure, and/or the like, various embodiments of the technology disclosed herein may be implemented in a manner that enables a great deal of flexibility and customization as described herein.

All definitions, as defined and used herein, should be understood to control over dictionary definitions, definitions in documents incorporated by reference, and/or ordinary meanings of the defined terms.

As used herein, in particular embodiments, the terms “about” or “approximately” when preceding a numerical value indicates the value plus or minus a range of 10%. Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. That the upper and lower limits of these smaller ranges can independently be included in the smaller ranges is also encompassed within the disclosure, subject to any specifically excluded limit in the stated range. Where the stated range includes one or both of the limits, ranges excluding either or both of those included limits are also included in the disclosure.

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

While specific embodiments of the present disclosure have been outlined above, many alternatives, modifications, and variations will be apparent to those skilled in the art. Accordingly, the embodiments set forth herein are intended to be illustrative, not limiting. Various changes may be made without departing from the spirit and scope of the disclosure. Where methods and steps described above indicate certain events occurring in a certain order, those of ordinary skill in the art having the benefit of this disclosure would recognize that the ordering of certain steps may be modified and such modification are in accordance with the variations of the invention. Additionally, certain of the steps may be performed concurrently in a parallel process when possible, as well as performed sequentially as described above. The embodiments have been particularly shown and described, but it will be understood that various changes in form and details may be made.

1. A method of forming an electrochemical cell in a battery formation system, the electrochemical cell including an anode material disposed on an anode current collector, a cathode material disposed on a cathode current collector, and a separator disposed between the anode material and the cathode material, the method comprising;
transferring energy from an energy storage system to the battery formation system to charge the electrochemical cell;
transferring energy from the electrochemical cell to the energy storage system to prevent heat energy dissipation into the formation system, wherein the energy transferred is direct current (DC).

2. The method of claim 1, wherein transferring energy from the energy storage system to the battery formation system is at a voltage of at least about 400 V.

3. The method of claim 1, wherein the energy is transferred between the formation system and the energy storage system without an alternating current (AC) transformer.

4. The method of claim 1, wherein energy losses from the formation of the electrochemical cell are reduced by at least about 100% of a full capacity of the electrochemical cell, as compared to a formation of an individual electrochemical cell without the use of the energy storage system.

5. The method of claim 1, further comprising:
providing backup energy for a building via the energy storage system.

6. The method of claim 1, wherein the energy storage system provides energy to at least one of a facility, a campus, or a macro grid level DC supply with a voltage of at least about 400 V.

7. The method of claim 1, wherein the energy storage system provides energy to at least one of a facility, a campus, or a macro grid level DC supply with a voltage of less than about 100 V.

8. The method of claim 1, wherein the energy storage system provides power to at least one of a facility, a campus, or a grid level AC power supply and backup.

9. The method of claim 1, further comprising:
transferring energy from a renewable power source to the energy storage system; and
storing the energy from the renewable power source in the energy storage system.

10. The method of claim 9, wherein the renewable power source includes a solar array.

11. A system for forming an electrochemical cell module, the system comprising:
a first electrochemical cell module and a second electrochemical cell module connected in series, the first electrochemical cell module and the second electrochemical cell module configured to receive energy via an energy storage system;
a first switch connected in series with the first electrochemical cell module and a second switch connected in parallel with the first electrochemical cell module, the first switch and the second switch having:
a first configuration in which the first switch is closed and the second switch is open such that current moves through the first electrochemical cell module; and
a second configuration in which the first switch is open and the second switch is closed such that current moves directly to the second electrochemical cell module, bypassing the first electrochemical cell module; and
a controller configured to transition the first switch and the second switch between the first configuration and the second configuration, thereby directing current flow to charge and discharge the first electrochemical cell module and second electrochemical cell module.

12. The system of claim 11, further comprising:
a third switch connected in series with the second electrochemical cell module and a fourth switch connected in parallel with the second electrochemical cell module,
the third and fourth switches configured to open and close in response to signals received from the controller.

13. The system of claim 11, further comprising:
a DC load and a DC charge electrically connected in parallel with the energy storage system and the first electrochemical cell module and the second electrochemical cell module.

14. The system of claim 12, further comprising:
a first electronic circuitry electrically coupled to the first electrochemical cell module; and
a second electronic circuitry electrically coupled to the second electrochemical cell module,
the first electronic circuitry and the second electronic circuitry configured to measure voltages of the first electrochemical cell module and the second electrochemical cell module, respectively, to detect a faulty electrochemical cell module.

15. The system of claim 14, wherein upon detection of a faulty electrochemical cell module, the controller directs current away from the faulty electrochemical cell module and through a healthy electrochemical cell module such that the healthy electrochemical cell module can continue formation.

16. The system of claim 11, wherein the system includes a plurality of electrochemical cell modules, the plurality of electrochemical cell modules electrically connected to a plurality of switches configured to control current flow through the plurality of electrochemical cell modules.

17. The system of claim 16, wherein the energy storage system stores energy generated by formation of the plurality of electrochemical cell modules for alternative uses to prevent heat energy dissipation.

18. The system of claim 17, wherein the plurality of electrochemical cell modules have a DC electrical connection to the energy storage system such that energy is transferred between the plurality of electrochemical cells and the energy storage system without an AC transformer.

19. A system comprising:
an energy storage system configured to receive energy from one or more power sources;
a formation system including a plurality of electrochemical cells connected in series and configured to control current flow through the plurality of electrochemical cells via a controller electrically coupled to a plurality of switches,
the plurality of electrochemical cells connected to the energy storage system via a DC electrical connection such that energy is transferred between the plurality of electrochemical cells and the energy storage system without an AC transformer.

20. The system of claim 19, wherein the energy storage system stores energy generated by formation of the plurality of electrochemical cells for alternative uses to prevent heat energy dissipation.

21. The system of claim 19, wherein the energy storage system provides energy to at least one of a facility, a campus, or a macro grid level DC supply with a voltage of at least about 400 V.

22. The system of claim 19, wherein the energy storage system provides energy to at least one of a facility, a campus, or a macro grid level DC supply with a voltage of less than about 100 V.

23. The system of claim 19, wherein the energy storage system provides power to at least one of a facility, a campus, or a grid level AC power supply and backup.

24. The system of claim 19, wherein the energy storage system provides backup energy for a battery manufacturing facility.

25. The system of claim 24, wherein the energy storage system provides backup energy to at least one of a dry room, a manufacturing line, or an HVAC system.

26. The system of claim 19, wherein the one or more power sources includes a renewable power source.

27. The system of claim 26, wherein the one or more power sources includes a solar array that provides DC energy.
